(19) United States
(12) Patent Application Publication
(10) Pub. No.: US 2025/0125311 A1
(43) Pub. Date: Apr. 17, 2025

(54) SEMICONDUCTOR PACKAGES WITH STACKED MEMORY AND LOGIC

(71) Applicant: Samsung Electronics Co., Ltd., Suwon-si (KR)

(72) Inventors: JIN YANG, San Jose, CA (US); WOOPOUNG KIM, San Jose, CA (US)

(21) Appl. No.: 18/613,664

(22) Filed: Mar. 22, 2024

Related U.S. Application Data
(60) Provisional application No. 63/589,597, filed on Oct. 11, 2023.

(51) Int. Cl. H01L 25/065; H01L 23/00; H01L 23/538; H01L 25/18; H10B 10/00; H10B 12/00

(52) U.S. Cl. CPC H01L 25/0657; H01L 23/5389; H01L 24/08; H01L 24/16; H01L 25/18; H10B 10/00; H10B 12/00; H01L 2224/08145; H01L 2224/16145; H01L 2225/06541; H01L 2924/1436; H01L 2924/1437

(57) ABSTRACT

A semiconductor package may include a first redistribution line structure; a die on the first redistribution line structure; a first memory device on a first surface of the die; a second redistribution line structure on a second surface of the die opposite from the first surface; a second memory device on the second redistribution line structure; and at least one semiconductor chip on the second redistribution line structure and electrically connected to the first memory device and to the second memory device. The first memory device may be a static RAM (SRAM), and the second memory device may be a dynamic RAM (DRAM).

### CROSS-REFERENCE TO RELATED APPLICATION

The present application claims the benefit of priority to U.S. Provisional Application No. 63/589,597, filed on Oct. 11, 2023, and the entire contents of the above-identified application are incorporated by reference as if set forth herein.

### TECHNICAL FIELD

The inventive concepts disclosed herein relate to semiconductor packages, and in particular relate to semiconductor packages having package architectures of stacked memory chips and logic chips.

### BACKGROUND

In a computing architecture, a processing component (such as a central processing unit (CPU), graphics processing unit (GPU), or the like) may fetch data from one or more memory devices, such as static random access memory (SRAM) devices acting as a cache (which is relatively faster but relatively lower capacity), and/or a relatively higher capacity but relatively slower dynamic RAM (DRAM).

Increasing development within electronic industries and increasing demands from customers have resulted in electronic devices which have been further miniaturized and multi-functionalized. Accordingly, semiconductor packages including a plurality of semiconductor chips or dies are under consideration and development.

### SUMMARY

According to some aspects of the present inventive concepts, a semiconductor package is provided. The semiconductor package may include: a first redistribution line structure comprising a first insulating layer and a first redistribution line pattern; a die on the first redistribution line structure; a first memory device on a first surface of the die; a second redistribution line structure on a second surface of the die opposite from the first surface, the second redistribution line structure comprising a second insulating layer and a second redistribution line pattern; a second memory device on the second redistribution line structure; and at least one semiconductor chip on the second redistribution line structure and electrically connected to the first memory device and to the second memory device. In some embodiments, the first memory device may be a static RAM (SRAM) device, and the second memory device may be a dynamic RAM (DRAM) device.

According to some aspects of the present inventive concepts, a semiconductor package may include a first redistribution line structure having first and second portions, the first redistribution line structure comprising a first insulating layer and a first redistribution line pattern; a die on the first redistribution line structure; a first memory device on a first surface of the die; a second redistribution line structure on a second surface of the die opposite from the first surface, the second redistribution line structure comprising a second insulating layer and a second redistribution line pattern; and a second memory device on an upper surface of the second redistribution line structure. The first memory device may be overlapped in a horizontal direction by the first and second portions of the first redistribution line structure.

According to some aspects of the present inventive concepts, a method of forming a semiconductor package may include: forming a first redistribution line structure comprising a first insulating layer and a first redistribution line pattern; attaching a first memory device to a first surface of a die; attaching the first surface of the die to the first redistribution line structure; forming a second redistribution line structure on a second surface of the die opposite from the first surface, the second redistribution line structure comprising a second insulating layer and a second redistribution line pattern; and attaching a second memory device to a surface of the second redistribution line structure that is opposite from a surface of the second redistribution line structure facing the die.

The present disclosure is not limited to the above-described embodiments and inventive concepts, and other embodiments and inventive concepts are provided in the figures and the detailed description thereof.

### BRIEF DESCRIPTION OF THE DRAWINGS

FIG. 1 is a cross-sectional view of a semiconductor package 1 according to some embodiments.

FIGS. 2A, 2B, 2C, 2D, 2E, and 2F are cross-sectional views for explaining a method of manufacturing a portion of a semiconductor package, according to some embodiments.

FIGS. 3A and 3B are cross-sectional views for explaining a method of manufacturing a portion of a semiconductor package, according to some embodiments.

FIGS. 4A and 4B are cross-sectional views for explaining a method of manufacturing a portion of a semiconductor package, according to some embodiments.

FIGS. 5A, 5B, and 5C are cross-sectional views for explaining a method of manufacturing a portion of a semiconductor package, according to some embodiments.

Like reference numerals may refer to corresponding parts throughout the drawings.

### DETAILED DESCRIPTION

High bandwidth memory (HBM) has been introduced and has been integrated directly with computing engines using advanced packaging, including 2.5D and 3D IC packages. Placing HBM closer to processor components may help to reduce latency and increase memory bandwidth. However, latency may remain in transferring a large amount of data between processor components and HBM through a silicon interposer or active silicon. Additionally, increasing power consumption in such packaging raises concerns regarding thermal management and energy efficiency management.

Accordingly, some embodiments of the inventive concepts of the present disclosure provide semiconductor package architectures that supply improved computing performance and memory performance and achieve acceptable thermal properties and/or energy management. For example, some embodiments of the inventive concepts may provide a memory device having a first type (e.g., a SRAM memory device) and a memory device having a second type (e.g., a DRAM memory device) along with processing components in one stacked architecture (e.g., one silicon stack-up). This may combine advantages of both the first memory type (e.g., faster and low latency, lower power down to 1 watt (W)) and the second memory type (e.g., higher capacity, up to 32 gigabytes (GB) or more), and may provide improved thermal properties and/or energy management. However, the present disclosure is not limited to such embodiments or advantages.

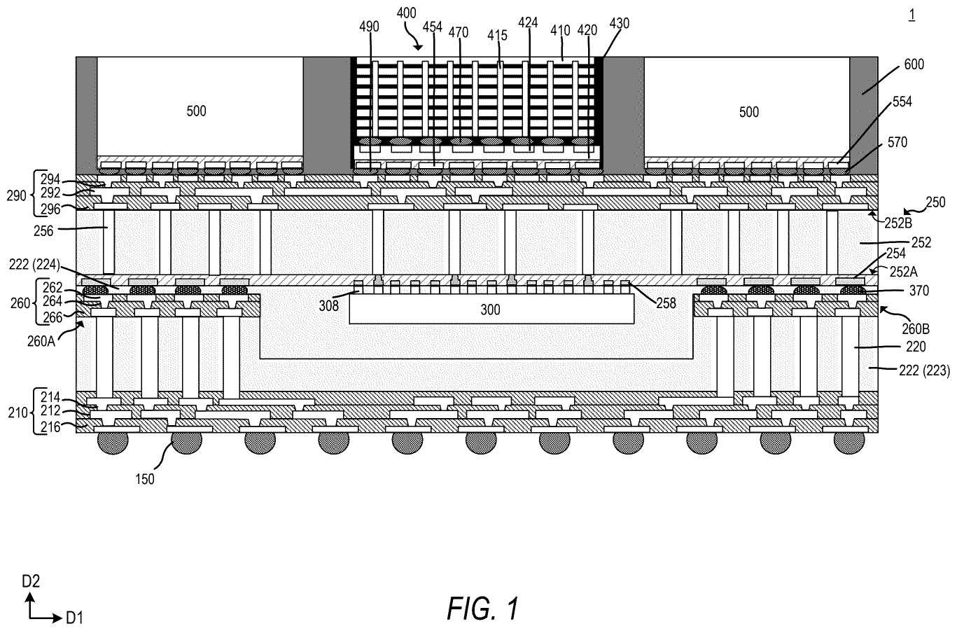

FIG. 1 is a cross-sectional view of a semiconductor package 1 according to some embodiments. Referring to FIG. 1, the semiconductor package 1 may include a lower redistribution line structure 210, a middle redistribution line structure 260, a first memory device 300, a die 250, an upper redistribution line structure 290, a second memory device 400, and/or at least one semiconductor chip 500 (two semiconductor chips 500 are shown in FIG. 1). The middle redistribution line structure 260, the first memory device 300, and the die 250 may be between the lower redistribution line structure 210 and the upper redistribution line structure 290 in a vertical direction D2, and the second memory device 400 and the at least one semiconductor chip 500 may be on the upper redistribution line structure 290 in the vertical direction D2. The first memory device 300 may be on a first side of the die 250, and the second memory device may be on a second side of the die 250 opposite from the first side in the vertical direction D2.

The lower redistribution line structure 210 may include a plurality of lower insulating layers 216, a plurality of lower redistribution line patterns 212 on at least one of top surfaces and bottom surfaces of the plurality of lower insulating layers 216, and a plurality of lower via patterns 214 penetrating at least one of the plurality of lower insulating layers 216 and contacting at least some of the plurality of lower redistribution line patterns 212.

Each lower insulating layer 216 may be formed from, for example, an organic material layer, and in some embodiments each lower insulating layer 216 may include an organic compound. According to some embodiments, each of the plurality of lower insulating layers 216 may be formed from an organic polymer material (e.g., photosensitive polyimide (PSPI)).

Each lower redistribution line pattern 212 and lower via pattern 214 may include a metal, such as copper (Cu), tungsten (W), titanium (Ti), titanium tungsten (TiW), titanium nitride (TiN), tantalum (Ta), tantalum nitride (TaN), chromium (Cr), aluminium (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), an alloy thereof, or a metal nitride, but the present disclosure is not limited thereto.

In some embodiments, a portion of the lower redistribution line patterns 212 may be integrally formed together with a portion of the lower via patterns 214. For example, at least some of the lower redistribution line patterns 212 may be integrally formed with at least some of the lower via patterns 214. In FIG. 1, the lower redistribution line patterns 212 are seen as within the lower insulating layers 216 of the plurality of lower insulating layers 216, but is not limited thereto. According to some embodiments, some of the lower redistribution line patterns 212 may be on a top surface of an uppermost layer and/or on a bottom surface of a lowermost layer of the plurality of lower insulating layers 216.

A plurality of connection pillars 220 may be on the lower redistribution line structure 210. Each of the plurality of connection pillars 220 may be on the lower redistribution line structure 210 and spaced apart from the first memory device 300 in a horizontal direction D1. The plurality of connection pillars 220 may be on portions of the plurality of lower redistribution line patterns 212, respectively. The connection pillars 220 may be connected to, for example, an uppermost one of the plurality of lower redistribution line patterns 212 of the lower redistribution line structure 210. In some embodiments, the connection pillars 220 may be formed of, for example, the same material as the lower redistribution line pattern 212 or the lower via pattern 214.

The middle redistribution line structure 260 may be positioned on the connection pillars 220. The middle redistribution line structure 260 may include at least one middle insulating layer 266, a plurality of middle redistribution line patterns 262 on a top surface or bottom surface of the middle insulating layers 266, and/or a plurality of middle via patterns 264 penetrating the middle insulating layers 266 and contacting portions of the plurality of middle redistribution line patterns 262, respectively.

The middle redistribution line patterns 262, the middle via patterns 264, and the middle insulating layers 266 may be identical to the lower redistribution line patterns 212, the lower via patterns 214, and the lower insulating layers 216, respectively, and thus details thereof are not provided again. In some embodiments, the number of layers of the middle redistribution line structure 260 may be smaller than the number of layers of the lower redistribution line structure 210, but the present disclosure is not limited thereto. The middle redistribution line structure 260 may be split or divided in the horizontal direction D1 into a first middle redistribution line structure portion 260A and a second middle redistribution line structure portion 260B.

The connection pillars 220 may interconnect the lower redistribution line patterns 212 of the lower redistribution line structure 210 and the middle redistribution line patterns 262 of the middle redistribution line structure 260. For example, the connection pillars 220 may contact and electrically interconnect the uppermost one of the plurality of lower redistribution line patterns 212 of the lower redistribution line structure 210 and the lowermost one of the middle redistribution line patterns 262 of the middle redistribution line structure 260.

The die 250 may be on the middle redistribution line structure 260. The die 250 may include a first semiconductor substrate 252. The first semiconductor substrate 252 may include a first surface 252A, which may be an active surface or may be an interface on which a transistor layer is formed (designated by hatching in FIG. 1), and the first semiconductor substrate 252 may also include a second surface 252B, which may be opposite from the first surface 252A in the vertical direction D2 and which may be an inactive surface. The first semiconductor substrate 252 may include a semiconductor element, such as germanium (Ge), or a compound semiconductor, such as silicon carbide (SiC), gallium arsenide (GaAs), indium arsenide (InAs), or indium phosphide (InP).

The die 250 may further include first chip pads 254 on the first surface 252A of the first semiconductor substrate 252 thereof. The first chip pads 254 of the die 250 may be connected to the middle redistribution line pattern 262 of the middle redistribution line structure 260 via a chip connection member 370. The chip connection member 370 may be, for example, a bump, solder ball, or a conductive pillar.

In some embodiments, the die 250 may include a wiring pattern (not shown) on a surface thereof (e.g., the second surface 252B). The wiring pattern may include one or more connection line wirings within one layer, but is not limited thereto. According to some embodiment, the wiring pattern may include connection line wirings within a plurality of layers and via plugs interconnecting the connection line wiring of different layers.

At least one transistor may be formed in the first semiconductor substrate 252 on the first surface 252A. The die 250 may include logic components and may be a logic die. In some embodiments, the die 250 may be configured to provide functionality including (but not limited to), e.g., data or signal routing, memory control, input/output interfacing, or the like.

Vias, e.g., through-substrate vias or through-silicon vias (TSVs) 256 may be formed in the first semiconductor substrate 252 and may penetrate or extend through the first semiconductor substrate 252 from the first surface 252A to the second surface 252B of the first semiconductor substrate 252. The vias 256 may have a plug structure and may be provided in a via hole (not shown) of the first semiconductor substrate 252. In some embodiments, a via 256 may make contact with a first chip pad 254 on the first surface 252A of the first semiconductor substrate 252.

The die 250 may include bonding pads 258 on the first surface 252A of the first semiconductor substrate 252 thereof. In some embodiments, a via 256 in the first semiconductor substrate 252 may make contact with a bonding pad 258 on the first surface 252A of the first semiconductor substrate 252 thereof, for example via electrical routing or vias. Not all electrical connections are shown in FIG. 1 for case of understanding.

The first memory device 300 may be provided on and coupled to the first surface 252A of the die 250. The first memory device 300 may be a static RAM (SRAM) memory device (e.g., a SRAM memory chip). The first memory device 300 may include bonding pads 308. The first memory device 300 may be arranged on the die 250 such that the bonding pads 308 of the first memory device 300 face the bonding pads 258 of the die 250. The bonding pads 308 of the first memory device 300 and the bonding pads 258 of the die 250 may be bonded to each other, e.g., by Cu—Cu hybrid bonding.

The first memory device 300 may be arranged to be between the first middle redistribution line structure portion 260A and the second middle redistribution line structure portion 260B in the horizontal direction D1. The first memory device 300 may be arranged to be overlapped by the first middle redistribution line structure portion 260A and the second middle redistribution line structure portion 260B in the horizontal direction D1.

A filling insulating layer 222 may be in (and may fill) an area between the lower redistribution line structure 210 and the die 250. The filling insulating layer 222 may be on and surround sidewalls of the connection pillars 220 and the first memory device 300. The filling insulating layer 222 may be on the first surface 252A of the first semiconductor substrate 252 of the die 250. The filling insulating layer 222 may be on exposed surfaces of the middle redistribution line structure 260 (and the first and second middle redistribution line structure portions 260A and 260B thereof) and of chip connection members 370 between the die 250 and the middle redistribution line structure 260. The filling insulating layer 222 may include, for example, epoxy molding compound (EMC) or a polymer material. As described in greater detail below, the filling insulating layer 222 may include a first filling insulating material layer 223 and a second filling insulating material layer 224. The first filling insulating material layer 223 and a second filling insulating material layer 224 may include different materials, or may include the same material. In some embodiments, the first filling insulating material layer 223 and second filling insulating material layer 224 may be or may include embedded molding materials, epoxy molding compound (EMC), or a polymer material.

The upper redistribution line structure 290 may be positioned on the second surface 252B of the first semiconductor substrate 252 of the die 250. The upper redistribution line structure 290 may include at least one upper insulating layer 296, a plurality of upper redistribution line patterns 292 on a top surface or a bottom surface of the at least one upper insulating layer 296, and/or a plurality of upper via patterns 294 penetrating the upper insulating layer 296 and contacting portions of the plurality of upper redistribution line patterns 292, respectively.

The upper redistribution line patterns 292, the upper via patterns 294, and the upper insulating layers 296 may be identical to the lower redistribution line patterns 212, the lower via patterns 214, and the lower insulating layers 216, respectively, and thus details thereof are not provided again. In some embodiments, the number of layers of the upper redistribution line structure 290 may be smaller than or greater than the number of layers of the lower redistribution line structure 210, but the present disclosure is not limited thereto.

The second memory device 400 may be on the upper redistribution line structure 290. The second memory device 400 may be connected to the upper redistribution line structure 290 via device connection members 490. In some embodiments, the second memory device 400 may include a stacked memory device. The second memory device 400 may be a stacked dynamic RAM (DRAM) device.

For example, the second memory device 400 may include a plurality of memory dies 410. Although the second memory device 400 includes eight memory dies 410 in FIG. 1, the number of memory dies is not limited thereto and may be variously changed. For example, the second memory device 400 may include four, twelve, sixteen, or a greater number of memory dies 410. Each of the memory dies 410 may include a memory cell array. The first memory device 300 may also include a memory cell array.

The plurality of memory dies 410 may be stacked on a logic die 420. The logic die 420 may be referred to as an interface die, or a base logic die.

Each of the memory dies 410 and the logic die 420 may include internal chip pads, which are shown in FIG. I only for the logic die 420 as internal chip pads 424. Internal connection members 470 may be between adjacent ones of the memory dies 410 and between the lowermost memory die 410 and the logic die 420. The internal connection members 470 may be, for example, bumps, solder balls, or conductive pillars.

Each of the memory dies 410 may include a through silicon via (TSV) 415. The TSVs are shown in aggregate in FIG. 1, e.g., without illustration of connection members between the memory dies 410. The logic die 420 and the memory dies 410 may be stacked on and electrically connected to each other through the TSVs 415. Accordingly, the second memory device 400 may have a three-dimensional (3D) memory structure, in which a plurality of dies are stacked. For example, the second memory device 400 may be implemented based on a high bandwidth memory (HBM) or hybrid memory cube (HMC) standard.

The logic die 420 may include an active surface having at least one transistor therein. The active surface of the logic die 420 may face the upper redistribution line structure 290. The logic die 420 may include interface circuits for communication with other components of the semiconductor package 1 (e.g., the die 250, the first memory device 300, the at least one semiconductor chip 500) and may be electrically connected to various components of the semiconductor package 1 through the upper redistribution line structure 290. Signals and/or data received through the logic die 420 may be transmitted to the memory dies 410 through the TSVs 415. In some embodiments, the logic die 420 may include circuits providing functionality in addition to a routing of signals and/or data to and from the memory dies 410 of the second memory device 400. In some embodiments, the second memory device 400 may be or may be referred to as a custom HBM or “bufferless” HBM, which may be used to distinguish the second memory device 400 from a HBM according to a standard (e.g., a JEDEC standard) which utilizes processes (e.g., memory processes) to fabricate a buffer die to connect DRAM memory dies. In some embodiments, the logic die 420 may be fabricated using an advanced fabrication process and/or an advanced silicon node, and may not follow a JEDEC standard size, and a size of the logic die 420 may vary according to need.

Insulating adhesive layers (not shown) may be between the logic die 420 and the lowermost memory die 410 or between two adjacent memory dies among the plurality of memory dies 410. For example, the insulating adhesive layers may include a non-conductive film (NCF), non-conductive paste (NCP), an insulating polymer, or epoxy resin. The second memory device 400 may further include a molding layer 430, which covers side surfaces of the logic die 420 and the memory dies 410. For example, the molding layer 430 may include an epoxy mold compound (EMC).

The second memory device 400 may include second chip pads 454 which may be connected to the upper redistribution line structure 290 via the device connection members 490, which may be for example, a bump, solder ball, or a conductive pillar.

The at least one semiconductor chip 500 provided in the semiconductor package 1 may be or may include a processing component, and may be or may include, for example, a central processing unit (CPU) chip, a graphics processing unit (GPU) chip, or an application processor (AP) chip, a neural processing unit (NPU), a tensor processing unit (TPU), a vision processing unit (VPU), an image signal processor (ISP), and/or a digital signal processor (DSP), as non-limiting examples. For example, a first one of the at least one semiconductor chips 500 may be a one of a CPU chip, a GPU chip, or an AP chip, and a second one of the at least one semiconductor chips 500 may be a different one of a CPU chip, a GPU chip or an AP chip than the first one of the at least one semiconductor chips 500.

The at least one semiconductor chip 500 may include a second semiconductor substrate, and third chip pads 554. The third chip pads 554 of the at least one semiconductor chip 500 may be connected to an upper redistribution line pattern 292 of the upper redistribution line structure 290 via a chip connection member 570. The chip connection member 570 may be, for example, a bump, solder ball, or a conductive pillar.

The semiconductor package 1 may further include a molding layer 600, which may cover outer surfaces of the second memory device 400 and the at least one semiconductor chip 500. In some embodiments, the molding layer 600 may surround outer sidewalls or surfaces of the lower redistribution line structure 210, the filling insulating layer 222, the middle redistribution line structure 260, the die 250, and the upper redistribution line structure 290. The molding layer 600 may include, for example, an epoxy mold compound (EMC). In some embodiments, the molding layer 600 may provide or include a heat emitting or heat dissipation member. An external connection terminal 150 may be adhered to the lowermost layer of the lower redistribution line structure 210, and may provide connections to and from one or more external devices (not shown).

The semiconductor package 1 may include a first memory device 300 and a second memory device 400. The first memory device 300 may be a SRAM memory device and the second memory device 400 may be a DRAM memory device (e.g., a stacked DRAM memory device). Processing components (e.g., the die 250, logic die 420, and the at least one semiconductor chip 500) of the semiconductor package 1 may be provided with the first memory device 300 and the second memory device 400 directly in one stacked architecture (e.g., one silicon stack-up), permitting the processing components of the semiconductor package 1 to access both the SRAM of the first memory device 300 and the DRAM of the second memory device 400.

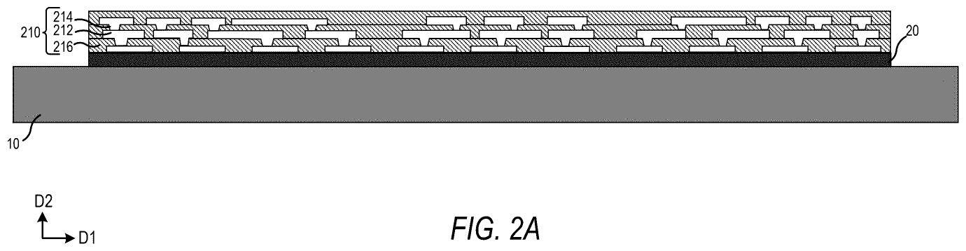

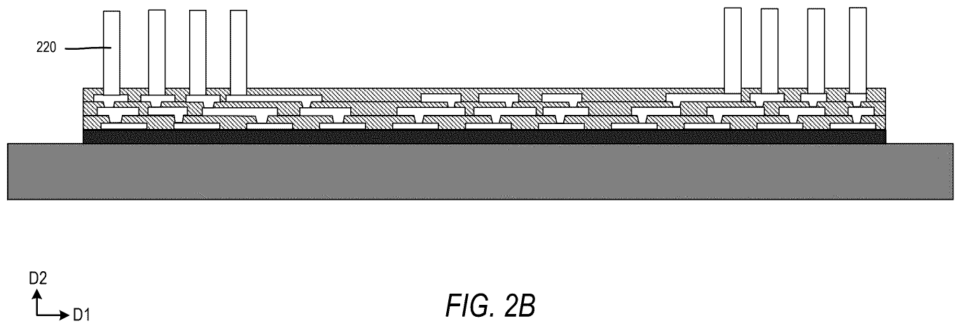

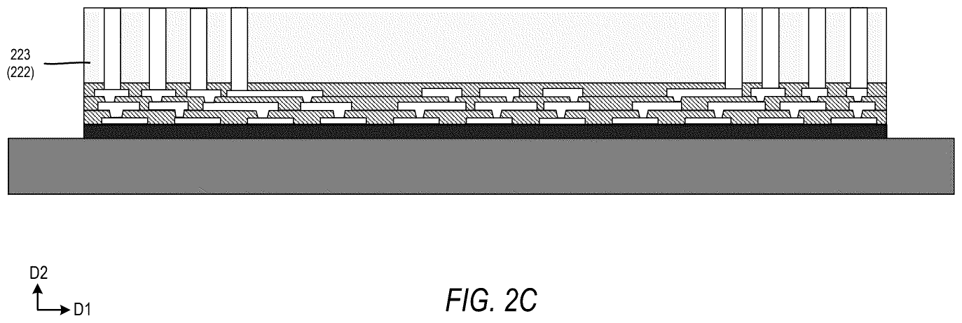

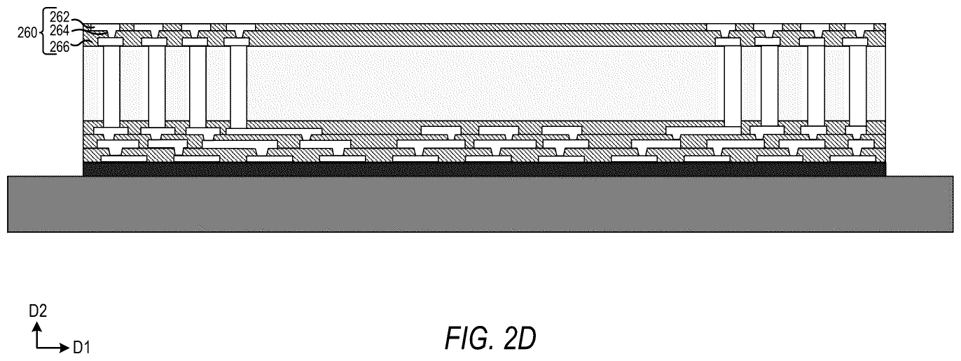

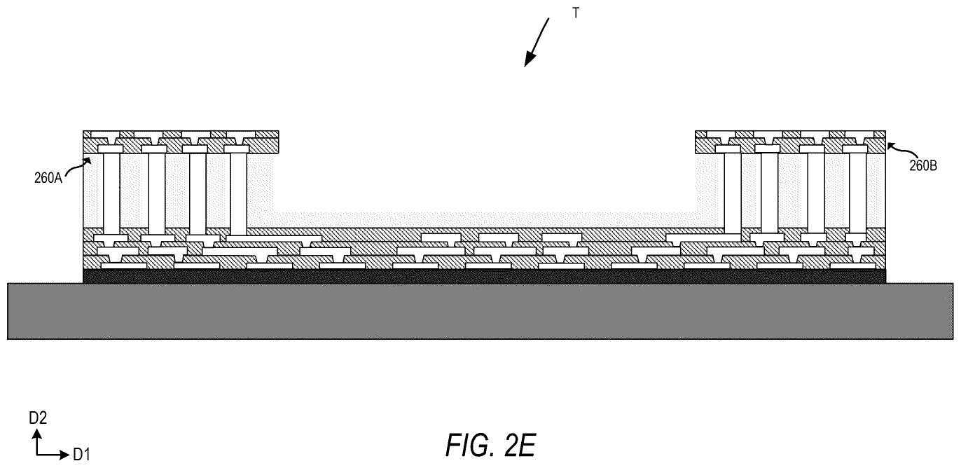

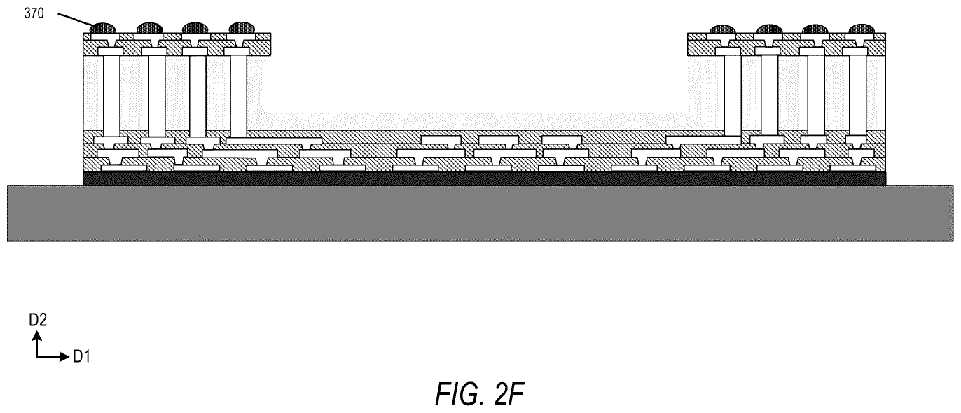

FIGS. 2A, 2B, 2C, 2D, 2E, and 2F are cross-sectional views for explaining a method of manufacturing a portion of a semiconductor package, according to some embodiments. For example, FIGS. 2A through 2F are cross-sectional views for explaining a method of manufacturing a first portion of the semiconductor package 1 of FIG. 1, where the first portion includes the lower redistribution line structure 210 and the middle redistribution line structure 260.

Referring to FIG. 2A, the lower redistribution line structure 210 may be formed on a carrier substrate 10 (e.g., a glass carrier). In some embodiments, a release film 20 may be adhered to an upper surface of the carrier substrate 10, and the lower redistribution line structure 210 may be formed on the release film 20. The lower redistribution line structure 210 may include the plurality of lower insulating layers 216, the lower redistribution line pattern 212 on the top surface or the bottom surface of each of the plurality of lower insulating layers 216, and/or the lower via pattern 214 penetrating each of the plurality of lower insulating layers 216.

The lower redistribution line structure 210 may be formed by sequentially stacking each of the plurality of lower insulating layers 216, and the lower redistribution line pattern 212 or both the lower via pattern 214 and the lower redistribution line pattern 212.

For example, a detailed method of manufacturing the lower redistribution line structure 210 is as follows. First, the lower insulating layer 216 of a lowermost layer is formed, and lower redistribution line patterns 212 may be formed on the lower insulating layer 216 of the lowermost layer. Then, a lower insulating layer 216 of a higher layer may be formed on the lowermost layer. A lower redistribution line pattern 212 may be formed in the higher layer, which may be performed concurrently with forming of the lower via pattern 214 in the lowermost layer, which may be connected to the lower redistribution line pattern 212 in the lowermost layer. By repeating such processes, the lower redistribution line structure 210 may be formed. Here, the lower via pattern 214 of a first layer may be integrally formed with a lower redistribution line pattern 212 of a second layer above the first layer, but the present disclosure is not limited thereto

Referring to FIG. 2B, connection pillars 220 may be formed on the lower redistribution line structure 210. The connection pillars 220 may be connected to the an uppermost portion of the lower redistribution line structure 210, for example, an uppermost lower redistribution line pattern 212 of the lower redistribution line structure 210.

In order to form the connection pillars 220, a mask pattern including an opening at a position where the connection pillar 220 is to be formed is formed on the lower redistribution line structure 210 and an exposed portion of the lower insulating layer 216 of the uppermost layer of the lower redistribution line structure 210 may be removed by using the mask pattern as an etch mask, so as to expose a portion of the lower redistribution line pattern 212. Then, the connection pillar 220 may be formed.

Referring to FIG. 2C, a first filling insulating material layer 223 may be formed on the lower redistribution line structure 210. The first filling insulating material layer 223 may be formed of, for example, epoxy molding compound (EMC) or polymer material. The filling insulating material layer may be formed on and surround sidewalls of the connection pillars 220.

Referring to FIG. 2D, the middle redistribution line structure 260 may be formed on the connection pillars 220 and the first filling insulating material layer 223. The middle redistribution line structure 260 may include the plurality of middle insulating layers 266, the middle redistribution line pattern 262 on the top surface or the bottom surface of each of the plurality of middle insulating layers 266, and/or the middle via pattern 264 penetrating each of the plurality of middle insulating layers 266. The middle redistribution line structure 260 may be formed via processes similar to that used to form the lower redistribution line structure 210, and a repeated description thereof is omitted here in the interest of brevity.

Referring to FIG. 2E, a trench T may be formed in the middle redistribution line structure 260 and in the first filling insulating material layer 223. The trench T may divide or split the middle redistribution line structure 260 into a first middle redistribution line structure portion 260A and a second middle redistribution line structure portion 260B, which may be separated or spaced apart from each other in the horizontal direction D1.

Referring to FIG. 2F, chip connection members 370 may be formed on the upper surface of the middle redistribution line structure 260. The chip connection members 370 may be for example, a bump, solder ball, or a conductive pillar. In some embodiments, the chip connection members 370 may be formed prior to the formation of the trench T.

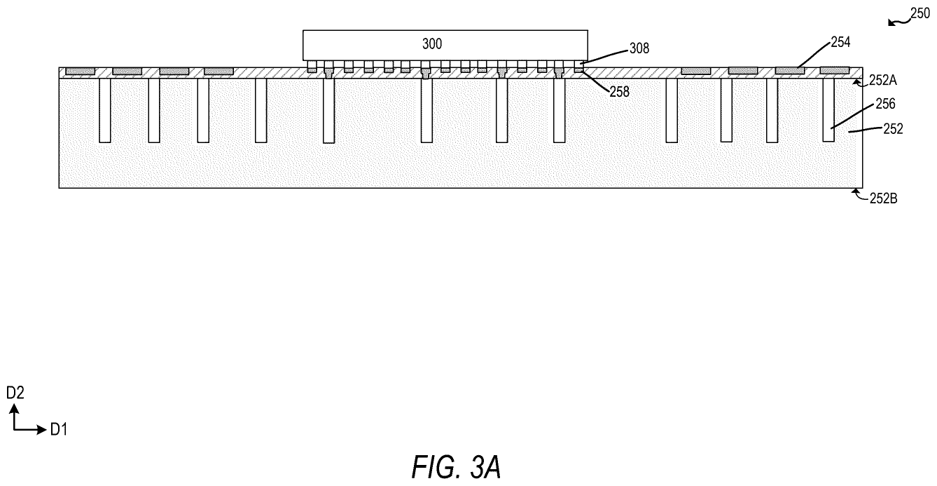

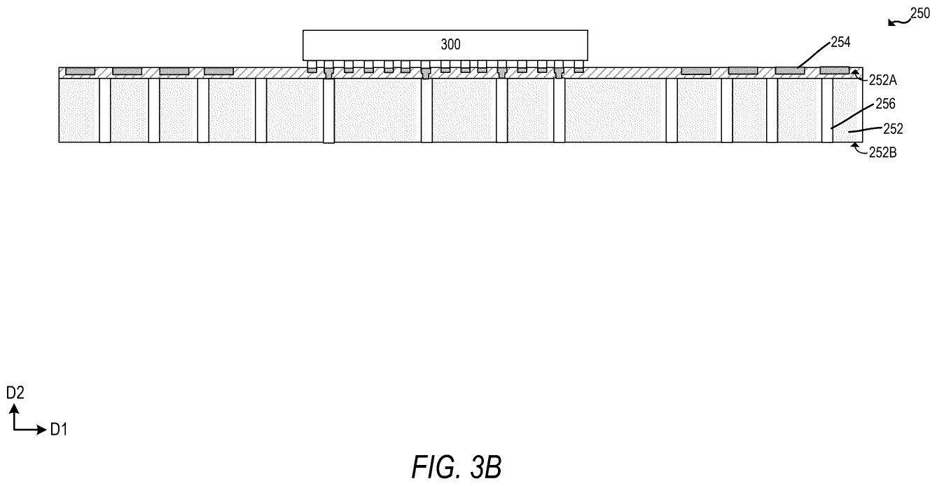

FIGS. 3A and 3B are cross-sectional views for explaining a method of manufacturing a portion of a semiconductor package, according to some embodiments.

Referring to FIG. 3A, the first memory device 300 may be provided on and coupled to the first surface 252A of the first semiconductor substrate 252 of the die 250. The first memory device 300 may be a static RAM (SRAM) memory device (e.g., a SRAM memory chip). The first memory device 300 may include the bonding pads 308 which may be bonded to the bonding pads 258 of the die 250. The bonding pads 308 of the first memory device 300 and the bonding pads 258 of the die 250 may be bonded to each other, e.g., by Cu—Cu hybrid bonding. The first semiconductor substrate 252 may have the vias 256 and the first chip pads 254 formed therein.

Referring to FIG. 3B, the first semiconductor substrate 252 of the die 250 may be thinned from the second surface 252B thereof, thereby exposing the vias 256 therein.

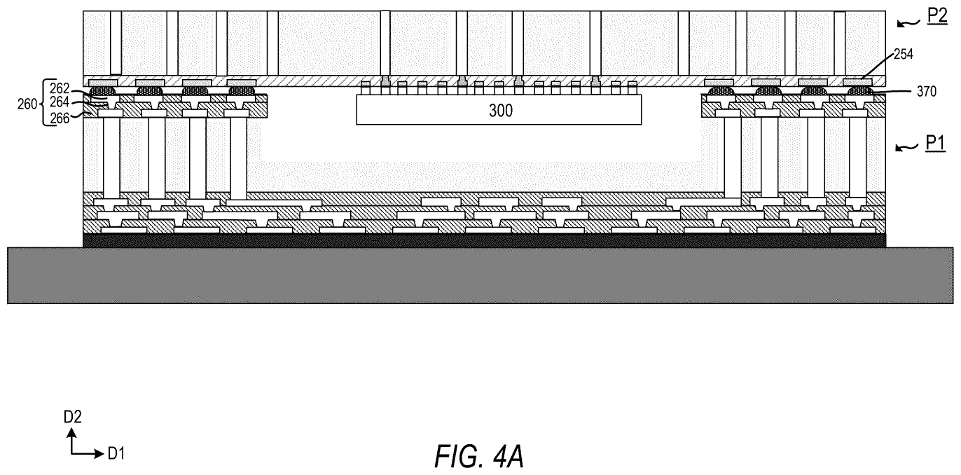

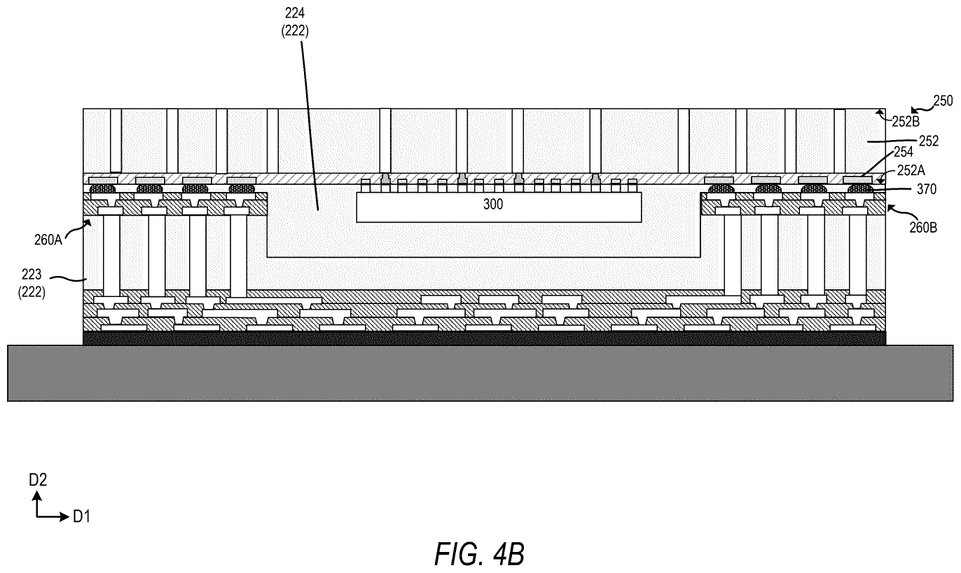

FIGS. 4A and 4B are cross-sectional views for explaining a method of manufacturing a portion of a semiconductor package, according to some embodiments. FIGS. 4A through 4B are cross-sectional views for explaining a method of manufacturing a third portion of the semiconductor package 1 of FIG. 1, where the third portion includes the first portion formed in FIGS. 2A through 2F and the second portion formed in FIGS. 3A and 3B.

Referring to FIG. 4A, the second portion (designated as P2) formed in FIGS. 3A and 3B may be stacked on and adhered to the first portion (designated as P1) formed in FIGS. 2A through 2F. More specifically, first chip pads 254 of the die 250 may be adhered to the chip connection members 370 formed on the upper surface of the middle redistribution line structure 260. The first memory device 300 may be inserted into the trench T formed in the first portion of the semiconductor package 1.

Referring to FIG. 4B, a second filling insulating material layer 224 may be formed on the lower redistribution line structure 210. The second filling insulating material layer 224 may be on and surround sidewalls and the first memory device 300. The second filling insulating material layer 224 may be on the first surface 252A of the first semiconductor substrate 252 of the die 250. The second filling insulating material layer 224 may be on exposed surfaces of the first and second middle redistribution line structure portions 260A and 260B and of chip connection members 370 between the die 250 and the middle redistribution line structure 260. The second filling insulating material layer 224 may be formed of, for example, epoxy molding compound (EMC) or polymer material. The first filling insulating material layer 223 and the second filling insulating material layer 224 may together form the filling insulating layer 222.

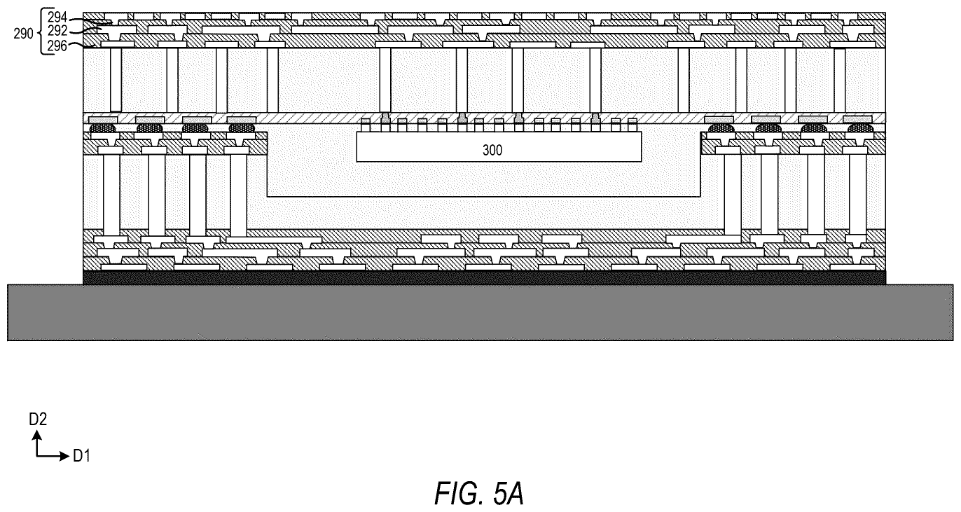

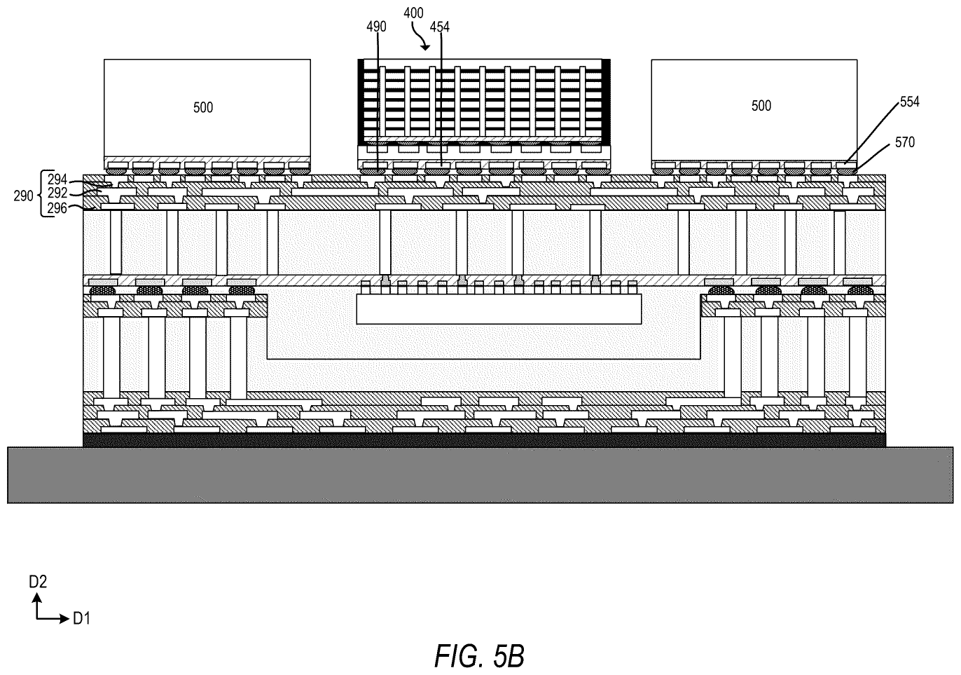

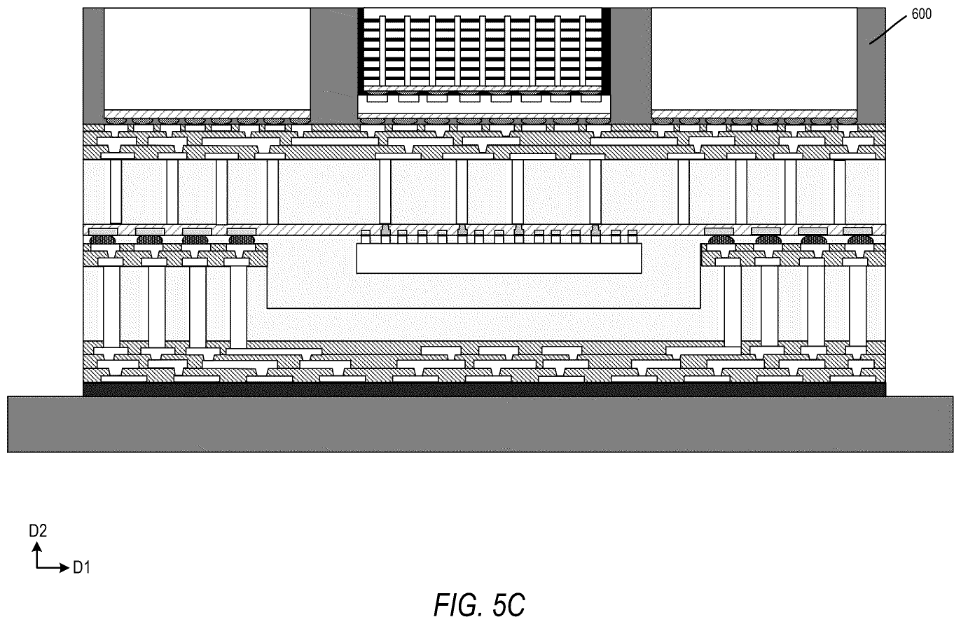

FIGS. 5A, 5B, and 5C are cross-sectional views for explaining a method of manufacturing the semiconductor package 1 of FIG. 1, including the portions manufactured in FIGS. 2A through 2F, FIGS. 3A and 3B, and FIGS. 4A and 4B.

Referring to FIG. 5A, the upper redistribution line structure 290 may be formed on the die 250. The upper redistribution line structure 290 may include the at least one upper insulating layer 296, the upper redistribution line pattern 292 on the top or bottom surface of the at least one upper insulating layer 296, and the upper via pattern 294 penetrating the at least one upper insulating layer 296. The upper redistribution line structure 290 may be formed via processes similar to that used to form the lower redistribution line structure 210, and a repeated description thereof is omitted here in the interest of brevity.

Referring to FIG. 5B, the at least one semiconductor chip 500 and the second memory device 400 may be adhered (in any order) on the upper redistribution line structure 290. For example, second chip pads 454 of the second memory device 400 may be adhered to the device connection members 490 formed on the upper surface of the upper redistribution line structure 290, and third chip pads 554 of the at least one semiconductor chip 500 may be adhered to chip connection members 570 formed on the upper surface of the upper redistribution line structure 290.

The at least one semiconductor chip 500 and the second memory device 400 may be manufactured prior to the formation of the semiconductor package 1 via separate processes.

Referring to FIG. 5C, the molding layer 600 may be formed, which may cover outer surfaces of the second memory device 400 and the at least one semiconductor chip 500. In some embodiments, the molding layer 600 may surround outer sidewalls or surfaces of the lower redistribution line structure 210, the filling insulating layer 222, the middle redistribution line structure 260, the die 250, and the upper redistribution line structure 290. The molding layer 430 may include, for example, an epoxy mold compound (EMC). Subsequent to the formation of the molding layer 600, a grinding operation may be performed on an upper surface thereof to expose upper surfaces of the second memory device 400 and the at least one semiconductor chip 500 (e.g., for attachment of cooling devices thereto).

Referring to FIG. 1, the carrier substrate 10 and the release film 20 may be separated from the lower redistribution line structure 210. The external connection terminal 150 may be adhered to the lower redistribution line structure 210. Accordingly, via processes illustrated in FIGS. 1, 2A through 2F, 3A and 3B, 4A and 4B, and 5A through 5C, the semiconductor package 1 of FIG. 1 may be formed.

Some examples of embodiments of the inventive concepts are described herein with reference to the accompanying drawings. Many different forms and embodiments are possible without deviating from the scope of the present inventive concepts. Accordingly, the present inventive concepts should not be construed as limited to the example embodiments set forth herein. Rather, these example embodiments are provided so that this disclosure will be thorough and complete and will convey the scope of the present invention to those skilled in the art. In the drawings, the sizes and relative sizes of layers and regions may be exaggerated for clarity. Like reference numbers refer to like elements throughout.

Example embodiments of the present inventive concepts are described herein with reference to cross-sectional views that are schematic illustrations of idealized embodiments and intermediate structures of example embodiments. As such, variations from the shapes of the illustrations as a result, for example, of manufacturing techniques and/or tolerances, are to be expected. Thus, example embodiments of the present inventive concepts should not be construed as limited to the particular shapes illustrated herein but include deviations in shapes that result, for example, from manufacturing, unless the context clearly indicates otherwise.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of the stated features, steps, operations, elements and/or components, but do not preclude the presence or addition of one or more other features, steps, operations, elements, components and/or groups thereof. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the scope of the present invention.

The above-disclosed subject matter is to be considered illustrative, and not restrictive, and the appended claims are intended to cover all such modifications, enhancements, and other embodiments, which fall within the scope of the inventive concepts. Thus, to the maximum extent allowed by law, the scope is to be determined by the broadest permissible interpretation of the following claims and their equivalents and shall not be restricted or limited by the foregoing detailed description.

What is claimed is:

1. A semiconductor package comprising:
a first redistribution line structure comprising a first insulating layer and a first redistribution line pattern;
a die on the first redistribution line structure;
a first memory device on a first surface of the die;
a second redistribution line structure on a second surface of the die opposite from the first surface, the second redistribution line structure comprising a second insulating layer and a second redistribution line pattern;
a second memory device on the second redistribution line structure; and
at least one semiconductor chip on the second redistribution line structure and electrically connected to the first memory device and to the second memory device.

2. The semiconductor package of claim 1, wherein the first memory device comprises a static RAM (SRAM), and wherein the second memory device comprises a dynamic RAM (DRAM).

3. The semiconductor package of claim 2, wherein the DRAM comprises a stacked DRAM comprising at least one memory die.

4. The semiconductor package of claim 1, wherein the second memory device comprises at least one memory die and a logic die configured to perform at least one function in addition to a routing of data to and from the at least one memory die.

5. The semiconductor package of claim 1, further comprising a third redistribution line structure comprising a third insulating layer and a third redistribution line pattern, the third redistribution line structure between the first and second redistribution line structures.

6. The semiconductor package of claim 5, further comprising:
a connection pillar between the first and third redistribution line structures; and
a filling insulating layer between the first redistribution line structure and the third redistribution line structure and surrounding the connection pillar.

7. The semiconductor package of claim 5, wherein the third redistribution line structure comprises a first redistribution line structure portion and a second redistribution line structure portion spaced apart from each other in a horizontal direction.

8. The semiconductor package of claim 5, wherein the first memory device horizontally overlaps with the third redistribution line structure.

9. The semiconductor package of claim 1, further comprising a molding layer surrounding the at least one semiconductor chip on the second redistribution line structure.

10. The semiconductor package of claim 1, wherein the first memory device comprises bonding pads that correspond to bonding pads on the first surface of the die.

11. A semiconductor package comprising:
a first redistribution line structure having first and second portions, the first redistribution line structure comprising a first insulating layer and a first redistribution line pattern;
a die on the first redistribution line structure;
a first memory device on a first surface of the die;
a second redistribution line structure on a second surface of the die opposite from the first surface, the second redistribution line structure comprising a second insulating layer and a second redistribution line pattern; and
a second memory device on an upper surface of the second redistribution line structure,
wherein the first memory device is overlapped in a horizontal direction by the first and second portions of the first redistribution line structure.

12. The semiconductor package of claim 11, wherein the second memory device comprises a stacked dynamic RAM (DRAM) device comprising at least one memory die.

13. The semiconductor package of claim 11, wherein the second memory device comprises at least one memory die and a logic die configured to perform at least one function in addition to a routing of data to and from the at least one memory die.

14. The semiconductor package of claim 11, wherein the first memory device comprises a static RAM (SRAM) device comprising a bonding pad that corresponds to a bonding pad on the first surface of the die.

15. A method of forming a semiconductor package, the method comprising:
forming a first redistribution line structure comprising a first insulating layer and a first redistribution line pattern;
attaching a first memory device to a first surface of a die;
attaching the first surface of the die to the first redistribution line structure;
forming a second redistribution line structure on a second surface of the die opposite from the first surface, the second redistribution line structure comprising a second insulating layer and a second redistribution line pattern; and
attaching a second memory device to a second surface of the second redistribution line structure that is opposite from a first surface of the second redistribution line structure facing the die.

16. The method of claim 15, further comprising:
forming a trench in the first redistribution line structure prior to attaching the first surface of the die to the first redistribution line structure,
wherein attaching the first surface of the die to the first redistribution line structure comprises inserting the first memory device into the trench.

17. The method of claim 15, further comprising forming a connection pillar, wherein the first redistribution line structure is on the connection pillar.

18. The method of claim 15, further comprising attaching at least one semiconductor chip to the second surface of the second redistribution line structure, wherein the at least one semiconductor chip is electrically connected to the first memory device and to the second memory device.

19. The method of claim 15, further comprising forming a molding layer on the second redistribution line structure.

20. The method of claim 15, wherein the first memory device comprises a static RAM (SRAM), and wherein the second memory device comprises a dynamic RAM (DRAM).
